(19) United States
(12) Patent Application Publication
(10) Pub. No.: US 2026/0156408 A1
(43) Pub. Date: Jun. 4, 2026

(54) HEADROOM PREDICTION FOR AN AUDIO AMPLIFIER

(71) Applicant: TEXAS INSTRUMENTS INCORPORATED, Dallas, TX (US)

(72) Inventors: Rejin Kanjavalappil Raveendranath, Bangalore (IN); Manojit Chakraborty, Bangalore (IN); Mukul Ratwani, Ajmer (IN)

(21) Appl. No.: 19/042,071

(22) Filed: Jan. 31, 2025

(30) Foreign Application Priority Data
Nov. 29, 2024 (IN) 202441093589

(51) Int. Cl. H04R 3/00; H03F 3/217

(52) U.S. Cl. CPC H04R 3/00; H03F 3/217; H03F 2200/03; H03F 2200/468; H03F 2200/471

(57) ABSTRACT

An apparatus includes an audio amplifier having a terminal and voltage estimator circuitry having a temperature input and an output. The voltage estimator circuitry is configured to generate a value at the output of the voltage estimator circuitry based on a temperature value at the temperature input of the voltage estimator circuitry. A boost converter has a first terminal, a second terminal, and a third terminal. The first terminal is coupled to an input voltage terminal. The second terminal of the boost converter is coupled to the terminal of the audio amplifier. The third terminal of the boost converter is coupled to the output of the voltage estimator circuitry. The boost converter is configured to generate a voltage at the second terminal of the boost converter based on the value.

### CROSS REFERENCE TO RELATED APPLICATION

This application claims priority to India Provisional Application No. 202441093589, titled “Feed forward class-H headroom prediction for class-D audio amplifiers,” filed Nov. 29, 2024, which is hereby incorporated by reference.

### BACKGROUND

Some audio systems include a class D amplifier which receives control signals from an audio controller and converts the control signals into an audio signal to drive a speaker. Some audio systems have a relatively low voltage power source. For example, a mobile device such as cell phone may be powered by a battery, e.g., 3.6V. To provide sufficient power to the class D amplifier to generate higher magnitude audio through the speaker, some audio systems may also include a boost converter to boost the relatively low supply voltage, e.g., battery voltage in a mobile device, to a higher voltage to power the class D amplifier.

### SUMMARY

In one example, an apparatus includes an audio amplifier having a terminal and voltage estimator circuitry having a temperature input and an output. The voltage estimator circuitry is configured to generate a value at the output of the voltage estimator circuitry based on a temperature value at the temperature input of the voltage estimator circuitry. A boost converter has a first terminal, a second terminal, and a third terminal. The first terminal is coupled to an input voltage terminal. The second terminal of the boost converter is coupled to the terminal of the audio amplifier. The third terminal of the boost converter is coupled to the output of the voltage estimator circuitry. The boost converter is configured to generate a voltage at the second terminal of the boost converter based on the value.

In another example, an apparatus includes an audio amplifier having a terminal. A voltage estimator circuitry has an output and is configured to generate a value at the output based on an audio signal and based on a load resistance. A boost converter has a first terminal, a second terminal, and a third terminal. The first terminal is coupled to an input voltage terminal. The second terminal is coupled to the terminal of the audio amplifier. The third terminal is coupled to the output of the voltage estimator circuitry. The boost converter is configured to generate a voltage at the second terminal based on the value.

In yet another example, an apparatus includes an audio amplifier having a terminal. A voltage estimator circuitry has a temperature input, a second input, and an output. The voltage estimator circuitry is configured to generate a value at the output of the voltage estimator circuitry based on a temperature value at the temperature input and based on an audio signal. A boost converter has a first terminal, a second terminal, and a third terminal. The first terminal is coupled to an input voltage terminal. The second terminal is coupled to the terminal of the audio amplifier. The third terminal is coupled to the output of the voltage estimator circuitry. The boost converter is configured to generate a voltage at the second terminal based on the value.

### BRIEF DESCRIPTION OF THE DRAWINGS

FIG. 1 is a schematic diagram of an audio system including a boost converter, a voltage estimator, and a clock selector, in an example.

FIG. 2 is a block diagram of the boost converter and clock selector of FIG. 1 as well as illustrating an example of how the voltage estimator is coupled to the boost converter, in an example.

FIG. 3 is a schematic diagram of a power stage of the boost converter of FIG. 1, in an example.

FIG. 4 is a schematic diagram of a clock generator of the boost converter of FIG. 1, in an example.

FIG. 5 is a diagram illustrating the operation of an envelope tracker of the boost converter of FIG. 1, in an example.

FIG. 6 is a graph illustrating the relationship between the peak reference current of the boost converter of FIG. 1 and its output voltage.

FIG. 7 is a schematic diagram of at least a portion of the boost converter of FIG. 1, in an example.

FIG. 8 is a graph of the relationship between the peak reference current of the boost converter of FIG. 1 and its output voltage illustrating the operation of a ripple compensation circuit, in an example.

FIG. 9 is a schematic diagram of at least a portion of the boost converter of FIG. 1, in another example.

FIG. 10 is a flow diagram, in an example.

FIG. 11 is a diagram of a processor coupled to memory containing code that is executable by the processor, in an example.

### DETAILED DESCRIPTION

The same reference numbers or other reference designators are used in the drawings to designate the same or similar (either by function and/or structure) features.

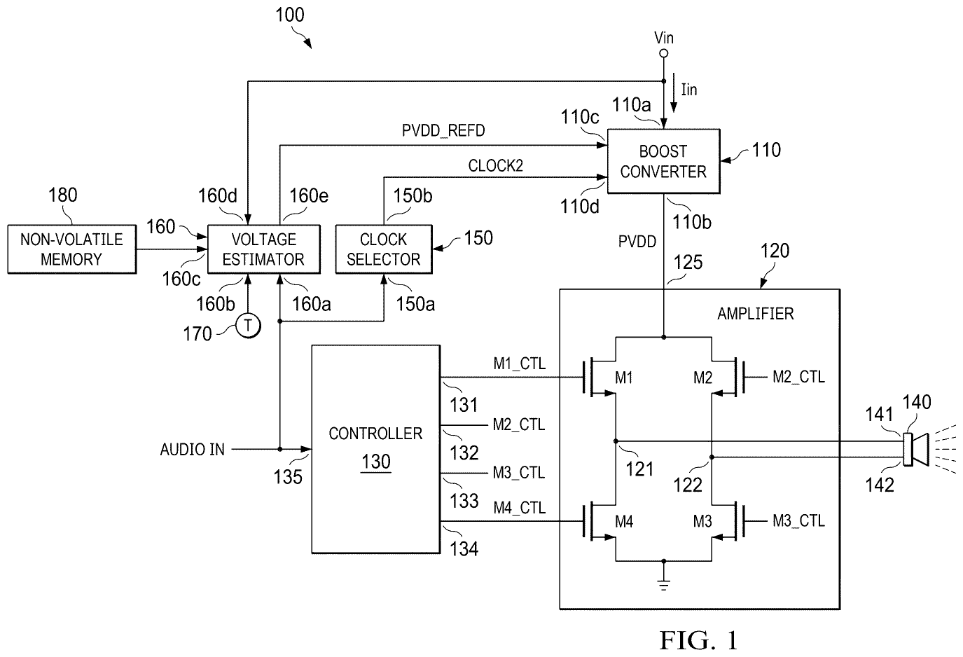

FIG. 1 is a schematic diagram of an audio system 100, in an example. Audio system 100 includes a boost converter 110, an amplifier 120, a controller 130, a speaker 140, a clock selector 150, a voltage estimator 160 (also referred to as voltage estimator circuitry), a temperature sensor 170, and a non-volatile memory (NVM) 180. Although amplifier 120 can be any suitable type of audio amplifier, in this example, amplifier 120 is a class D amplifier. Amplifier 120 includes transistors M1, M2, M3, and M4. Transistors M1-M4 are n-channel field effect transistors (NFETs) in this example but can be other types of transistors in other examples. The inputs to amplifier 120 are the gates of transistors M1-M4, which are coupled to corresponding output terminals 131, 132, 133, and 134 of controller 130. Output terminal 131 is coupled to the gate of transistor M1. Output terminal 132 is coupled to the gate of transistor M2. Output terminal 133 is coupled to the gate of transistor M3. Output terminal 134 is coupled to the gate of transistor M4. The source of transistor M1 is coupled to the drain of transistor M4 and provides an output terminal 121 of amplifier 120. Similarly, the source of transistor M2 is coupled to the drain of transistor M3 and provides the other output terminal 122 of amplifier 120. Speaker 140 has terminals 141 and 142 which are coupled to respective output terminals 121 and 122 of amplifier 120.

Boost converter 110 has a voltage input 110a, a voltage output 110b, a reference voltage control input 110c, and a clock input 110d. An input voltage Vin (e.g., a battery voltage) is provided to the voltage input 110a. The voltage output 110b of boost converter 110 is coupled to an input supply voltage terminal 125 of amplifier 120. Boost converter 110 converts the input voltage Vin to an output voltage, PVDD, at its voltage output 110b. Accordingly, voltage PVDD is provided to amplifier 120 to power the amplifier.

Controller 130 generates control signals M1_CTL, M2_CTL, M3_CTL, and M4_CTL at its corresponding output terminals 131-134 based on AUDIO IN. Controller 130 converts the analog input signal AUDIO IN to pulses as signals M1_CTRL, M2_CTRL, M3_CTRL, and M4_CTRL. Based on the logic levels of control signals M1_CTL, M2_CTL, M3_CTL, and M4_CTL, amplifier 120 has three phases of operation. In a first phase, with control signals M1_CTL and M3_CTL being logic high and control signals M2_CTL and M4_CTL being logic low, transistors M1 and M3 are on and transistors M2 and M4 are off. In a second phase, with control signals M2_CTL and M4_CTL being logic high and control signals M1_CTL and M3_CTL being logic low, transistors M2 and M4 are on and transistors M1 and M3 are off. In a third phase, with control signals M3_CTL and M4_CTL being logic high and control signals M1_CTL and M2_CTL being logic low, transistors M3 and M4 are on and transistors M1 and M2 are off. In another example, in the third phase, transistors M1 and M2 may be on and transistors M3 and M4 may be off. With transistors M1 and M3 on, relative to ground the voltage at output terminal 121 is PVDD and the voltage at output terminal 122 is ground (0V). Accordingly, the voltage of speaker terminal 141 relative to speaker terminal 142 is PVDD. With transistors M2 and M4 on, the voltage at output terminal 121 is 0V and the voltage at output terminal 122 is PVDD. Accordingly, the voltage of speaker terminal 141 relative to speaker terminal 142 is-PVDD. With transistors M3 and M4 on, or transistors M1 and M2 on, the voltage difference between at output terminals 121 and 122 is 0V.

Voltage estimator 160 has inputs 160a, 160b, 160c, and 160d and an output 160c. Clock selector 150 has an input 150a and an output 150b. Controller 130 has an audio input 135. An audio input signal, AUDIO IN, is provided to the audio input 135 of controller 130 and to the inputs 150a and 160a of clock selector 150 and voltage estimator 160, respectively. Temperature sensor 170 and non-volatile memory 180 are coupled to inputs 160b and 160c, respectively, of voltage estimator 160. Input 160d of voltage estimator 160 is coupled to voltage input 110a of boost converter 110 and receives the input voltage Vin. Output 160e of voltage estimator 160 is coupled to the reference voltage control input 110c of boost converter 110. Output 150b of clock selector 150 is coupled to clock input 110d of boost converter 110.

Voltage estimator 160 generates a value PVDD_REFD which is provided to the reference voltage control input 110c of boost converter 110. Boost converter 110 generates the PVDD voltage to audio amplifier 120 based on the PVDD_REFD value. By influencing the magnitude of PVDD, voltage estimator 160 assists boost converter 110 to operate with a suitable amount of headroom (PVDD minus the minimum PVDD level needed to operate the boost converter). A suitable amount of headroom means that the headroom is not so small as to cause amplifier 120 to exhibit non-linearity but not so high as to cause the boost converter to operate excessively inefficiently.

In one example, the PVDD_REFD value is a digital value and is determined based on one or more of multiple factors. In an example, voltage estimator 160 determines PVDD_REFD using the following equation:

$$PVDD\_REFD = k 1 * ( \frac{1}{RLOAD * VIN} ) * {AUDIO\_IN}^{2} + k 2 * ( 1 + \frac{RDSON}{RLOAD} ) * AUDIO\_IN + k 3 \qquad ( Eq . 1 )$$

where k1, k2, and k3 are fixed coefficients, RLOAD is the resistance of speaker 140, and RDSON is the on-resistance of transistors M1-M4. The coefficients k1, k2, and k3 may be determined apriori (e.g., at the factory) and stored in non-volatile memory 180. The resistance RLOAD depends on the speaker chosen to be speaker 140 and that value also can be stored in non-volatile memory 180 apriori.

In an example, the current from boost converter 110 that flows through amplifier 120 and speaker 140 flows through two of the four transistors during two of the phases of operation of the amplifier 120, as described above. Accordingly, current flows through on-resistances of the transistors resulting in a voltage drop across the transistors. The second term in Eq. (1),

$$k 2 * ( 1 + \frac{RDSON}{RLOAD} ) * AUDIO\_IN ,$$

forces boost converter 110 to produce a voltage PVDD to amplifier 120 higher than the voltage needed for speaker 140 to account for the voltage drops across the transistors in amplifier 120. Further, the on-resistance of transistors M1-M4 is temperature-dependent. In one example, the on-resistance RDSON can be calculated based on a second-order polynomial of temperature as:

$$RDSON = RDSON\_OTP * ( 1 + a 1 * T + a 2 * {T}^{2} ) \qquad ( Eq . 2 )$$

where T is temperature as determined, for example, by temperature sensor 170, a1 and a2 are coefficients determined apriori, and RDSON_OTP is the on-resistance of the transistors M1-M4 determined apriori at a known temperature such as room temperature. The coefficients a1 and a2 and RDSON_OTP may be stored in non-volatile memory 180.

In the application of FIG. 1, boost converter 110 functions as a power-limited converter because of the size of an inductor within the boost converter (described below) and saturation current constraints. Accordingly, in an example in which boost converter 110 is a peak current mode control converter, it may be useful to reduce the boost peak current limit while reducing output power to improve the battery current peak-to-average ratio. Reducing the boost peak current limit also limits the input power to the boost converter 110. As a result, the load regulation on PVDD is directly proportional to output power. The first term,

$$k 1 * ( \frac{1}{RLOAD * VIN} ) * {AUDIO\_IN}^{2} ,$$

in Eq. (1) above predicts the input current required by boost converter 110 based on the amplitude of AUDIO_IN and uses the estimated input current to predict the expected load regulation for the boost converter.

The third term in equation Eq. (1) above is coefficient k3. Coefficient k3 increases the magnitude of PVDD produced by boost converter 110 to account for out-of-band harmonics superimposed on the current produced by boost converter due to the switching behavior of transistors M1-M4 in amplifier 120. The value of coefficient k3 can be determined apriori and stored in non-volatile memory 180.

As will be further described below, boost converter 110 includes a power stage that includes, among other components, an inductor and a transistor. When the transistor is turned on, energy is stored in the inductor and the inductor current, which also is the boost converter's input current (Iin), increases linearly. When the transistor is turned off, the inductor's current decreases linearly. In the example described herein, boost converter 110 is a peak current mode control boost converter in which its inductor's current is compared to a peak reference current (I_LIM_REF). When the inductor current reaches the peak current threshold, the converter turns off the transistor. Accordingly, the inductor's current ramps up and down between the peak reference current, I_LIM_REF, and a lower current level. The peak-to-peak current difference of the inductor current is Iripple. The average inductor current, Iin_ave, is:

$$Iin\_ave = I\_LIM \_REF - \frac{Iripple}{2} \qquad ( Eq . 3 )$$

In the example of a mobile device, e.g., cellular telephone, tablet device, etc., the input voltage Vin may be supplied by the device's battery. The voltage of a mobile device's battery may be relatively small, e.g., 3.6V. The power delivered by boost converter 110 is a function of its input power. The input power, Pin, to boost converter 110 is the product of its input voltage, Vin, and the average input current, Iin_ave. The output power, Pout, from boost converter is Pin*Keff, where Keff represents the efficiency factor for the boost converter. For example, if Keff is 0.9 (90% efficient), Pout=Pin*0.9. Based on Eq. 1, the output power Pout from boost converter 110 is:

$$Pout = Vin * ( I\_MAX - \frac{Iripple}{2} ) * Keff \qquad ( Eq . 4 )$$

The switching frequency of boost converter 110 is Fsw. As described above, at higher switching frequencies, the ripple current Iripple is lower, and at lower switching frequencies, Iripple is higher. Based on Eq. 4, lower levels of Iripple results in higher levels of output power, Pout. However, higher switching frequencies also means an increase in switching losses within the boost converter. Clock selector 150 advantageously operates boost converter 110 to implement a lower switching frequency when the power draw needs of amplifier 120 are consistent with lower volume audio and to increase the switching frequency when the power draw needs of amplifier 120 are consistent with higher volume audio, thereby supplying the power demands of amplifier 120 in a power efficient manner.

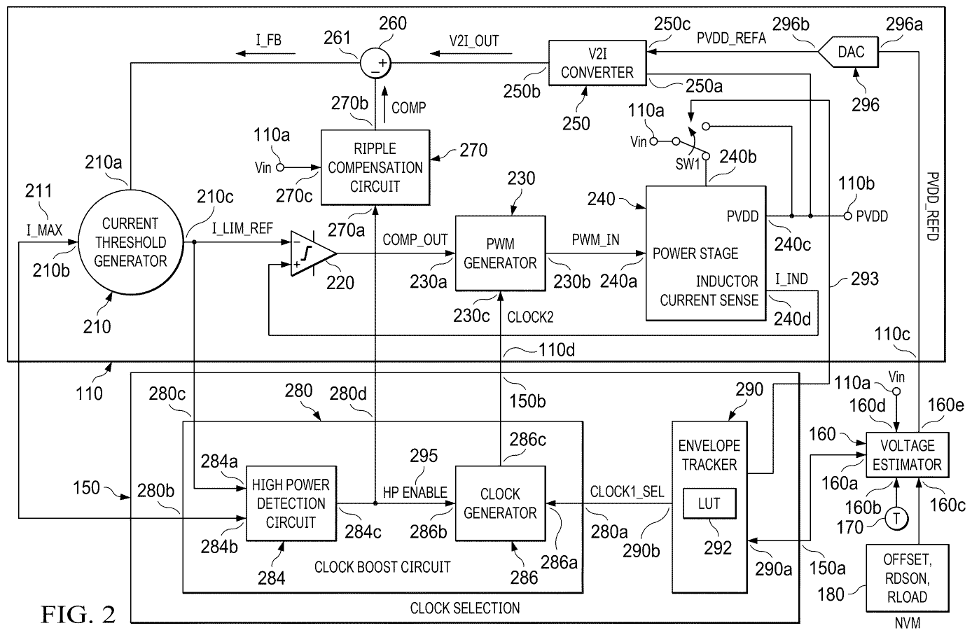

FIG. 2 is a diagram of boost converter 110 coupled to clock selector 150 and to voltage estimator 160. FIG. 2 includes a block diagram of boost converter 110 and clock selector 150. In this example, boost converter 110 includes a current threshold generator 210, a comparator 220, a pulse width modulator generator (PWM) 230, a power stage 240, a voltage-to-current (V2I) converter 250, a summer 260, a ripple compensation circuit 270, and a digital-to-analog converter (DAC) 296. Clock selector 150 includes a clock boost circuit 280 and an envelope tracker 290.

Power stage 240 has an input 240a, an input 240b coupled to the voltage input 110a, an output 240c coupled to the voltage output 110b, and an inductor current sense output 240d. At low amplitude levels of the audio signal, boost converter 110 may not be needed to provide a boosted voltage PVDD to amplifier 120. Bypass switch SW1 may be included, and coupled to voltage input 110a and to output 110b, to provide Vin directly to amplifier 120 as PVDD. As shown, switch SW1 may also be coupled to input 240b and to envelope tracker 290. As such, switch SW1 is controlled by a control signal 293 from envelope tracker 290, which determines an envelope of the audio input signal AUDIO IN. With switch SW1 in the state shown in FIG. 2, VIN is provided to power stage 240, and the power stage provides a boosted voltage PVDD that is greater than VIN to amplifier 120. In the other switch state, VIN is coupled directly to PVDD. When envelope tracker 290 determines that the envelope of AUDIO IN is below a threshold, the envelope tracker asserts control signal 293 to a logic state to change the state of switch SW1 to provide VIN to voltage output 110b.

The power stage's output 240c is coupled to an input 250a of V2I converter 250. The V2I converter 250 has an output 250b coupled to an input (+) of summer 260. Ripple compensation circuit 270 has an output 270b coupled to an input (−) of summer 260. The output 261 of summer 260 is coupled to an input 210a of current threshold generator 210. An input 210b of current threshold generator receives a value indicative of the maximum current (I_MAX) 211 that the boost converter is to allow through the inductor of its power stage 240. Output 210c of current threshold generator 210 is coupled to the negative (−) input of comparator 220. Inductor current sense output 240d of power stage 240 is coupled to the positive (+) input of comparator 220. Output 240d provides a signal I_IND indicative of the current through the inductor of the power stage. The output of comparator 220 is coupled to an input 230a of PWM generator 230. The output 230b of PWM generator 230 is coupled to the input 240a of power stage 240.

Envelope tracker 290 has an input 290a and an output 290b. Input 290a is coupled to the input 150a of clock selector 150. Clock boost circuit 280 has inputs 280a, 280b, and 280c and outputs 280d and 280c. Output 290b of envelope tracker 290 is coupled input 280a. The input 280b is configured to receive the value indicative of the maximum current I_MAX 211. Output 210c of current threshold generator 210 is coupled to input 280c. Output 280d is coupled to an input 270a of ripple compensation circuit 270, and output 280e is coupled through clock input 110d of boost converter 110 to an input 230c of PWM generator 230.

Output 160e of voltage estimator 160 is coupled through control input 110c of boost converter 110 to an input 296a of DAC 296. An output 296b of DAC 296 is coupled to an input 250c of V2I converter 250. DAC 296 converts the digital input value PVDD_REFD to an analog signal PVDD_REFA and provides PVDD_REFA to the input 250c of V2I converter 250. In one example, voltage estimator 160 is implemented in machine code executed on a processor. In another example, voltage estimator 160 is implemented in a digital circuit. In yet another example, voltage estimator 160 is implemented as an analog circuit. For example, bipolar junction transistor-based circuits can be used to implement the squaring function shown in Eqs. (1) and (2).

In one example, envelope tracker 290 is implemented in machine code executed on a processor and current threshold generator 210, comparator 220, PWM generator 230, power stage 250, V2I converter 250, summer 260, ripple compensation circuit 270, and clock boost circuit 280 are implemented as analog circuits. As described below, envelope tracker 290 determines the envelope of the audio input signal AUDIO IN. Envelope tracker 290 may have a look-up table (LUT) 292 which maps various ranges of audio input signal amplitude to corresponding switching frequencies. Envelope tracker 290 generates an output clock selection signal, CLOCK1_SEL, which corresponds to a frequency of a clock signal CLOCK1 using the magnitude of the envelope of the audio input signal as an index into the LUT 292. CLOCK1_SEL is provided to an input 286a of clock generator 286 (described below), responsive to which clock generator provides CLOCK1 at the frequency corresponding to CLOCK1_SEL. In one example, envelope tracker 290 generates CLOCK1_SEL responsive to which clock generator 286 generates a higher frequency clock signal CLOCK1 for higher levels of the envelope of the audio input signal AUDIO IN.

The clock selection signal CLOCK1_SEL is provided to input 280a of clock boost circuit 280. Clock boost circuit 280 includes a high power detection circuit 284 coupled to clock generator 286. High power detection circuit 284 includes inputs 284a and 284b coupled to the respective inputs 280b and 280c. High power detection circuit 284 includes an output 284c which is coupled to an input 286b of clock generator 286 and to input 270a of rippler compensation circuit 270. High power detection circuit 284 generates an output signal HP ENABLE 295 at its output 284c as described below. Clock generator 286 also has an input 286a that is coupled to input 280a and has an output 286c that is coupled to output 280c.

Clock boost circuit 280 generates its output clock signal CLOCK2 at its output 286c to PWM generator 230 to have a frequency corresponding to the clock selection signal CLOCK1_SEL or produces an output clock CLOCK2 at a higher frequency than otherwise indicated by CLOCK1_SEL. As described below, high power detection circuit 284 determines whether the power demand on boost converter 110 is within a threshold of its maximum output power capability. If power detection circuit 284 determines that the power demand on boost converter 110 is not within the threshold of its maximum output power capability, clock boost circuit 280 produces output clock CLOCK2 at a frequency corresponding to CLOCK1_SEL. However, if power detection circuit 284 determines that the power demand on boost converter 110 is within the threshold of its maximum output power capability, clock boost circuit 280 produces CLOCK2 at a frequency that is higher than that otherwise corresponding to CLOCK1_SEL. In one example, clock generator 286 produces CLOCK2 at a frequency that is double the highest clock frequency that clock generator 286 would otherwise produce based on CLOCK1_SEL if high power detection circuit 284 determines that boost converter 110 is providing power to amplifier 120 that is within the threshold of its maximum output power capability.

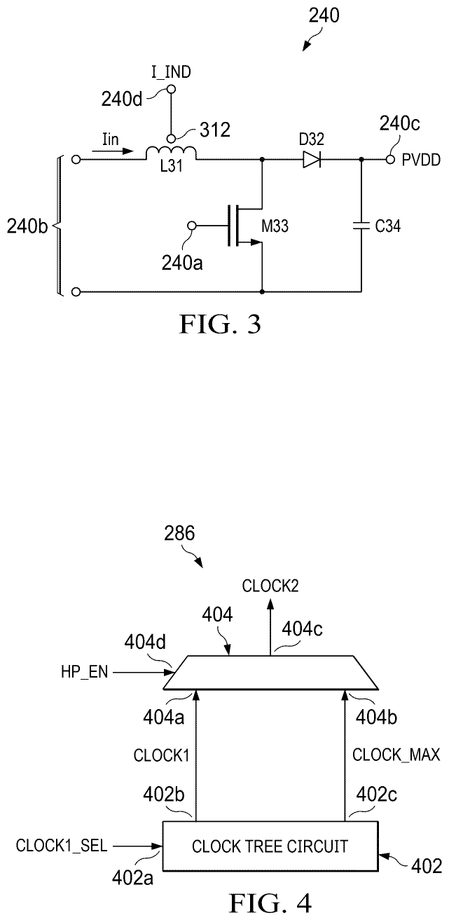

The clock signal CLOCK2 from clock boost circuit 280 is provided to PWM generator 230 to generate a PWM IN signal to power stage 240. As described above, in this example boost converter 110 is a peak mode control boost converter. Comparator 220 compares the inductor current sense signal I_IND from power stage 240 to the peak reference current I_LIM_REF, which is generated by current threshold generator 210. When the transistor of power stage 240 (transistor M33 in FIG. 3, described below) is on, the inductor's current increases (e.g., ramps up). When signal I_IND reaches the peak reference current I_LIM_REF, the output signal COMP_OUT from comparator 220 changes logic state from low to high. Responsive to a logic high assertion of COMP_OUT, PWM generator 230 forces its output signal PWM_IN to a logic state that turns off transistor M33 (described below) within power stage 240. Transistor M33 turns on again responsive to an edge (e.g., rising edge) of clock CLOCK2. The boost converter's output voltage PVDD is provided to input 250a of V2I converter, which converts the voltage PVDD to a current V2I_OUT. Output current V2I_OUT is proportional to output voltage PVDD. Based on a ripple compensation current COMP from ripple compensation circuit 270, summer 260 produces an output current I_FB, which also is proportional to output voltage PVDD.

In some examples, the maximum current value I_MAX 211 is programmed into boost converter 110, e.g., programmed into a register over a serial interface. In some examples, the maximum current value I_MAX 211 protects the inductor within power stage 240 from receiving a current in excess of its rated value. As described below, current threshold generator 210 generates the peak reference current I_LIM_REF to a value that is equal or less than the maximum current value I_MAX 211. For a given switching frequency of CLOCK2, the magnitude of output voltage PVDD varies inversely with output power—as output power from boost converter 110 increases, PVDD decreases and as output power decreases PVDD decreases. A control loop includes V2I converter 250, summer 260, and current threshold generator 210. The control loop adjusts the magnitude of peak reference current I_LIM_REF based on the magnitude of PVDD. As PVDD decreases, the magnitude of current I_FB decreases and the magnitude of peak reference current I_LIM_REF increases. As PVDD increases, the magnitude of current I_FB increases and the magnitude of peak reference current I_LIM_REF decreases. Accordingly, in some examples, I_LIM_REF being close to I_MAX 211 means that boost converter 110 is supplying close to its maximum power capability. High power detection circuit 284 may compare I_LIM_REF to I_MAX 211 to determine whether boost converter 110 is supplying power close to its maximum power capability.

FIG. 3 is a circuit diagram of power stage 240 in one example. Power stage 240 includes an inductor L31, a diode D32, a transistor M33, a capacitor C34, and a current sense circuit 312. Inductor L31 has a terminal coupled input 240b and another terminal coupled to the anode of diode D32. Capacitor C34 and the cathode of diode D32 are coupled to output 240c. Transistor M33 is an n-channel field effect transistor (NFET) in this example but can be implemented as another type of transistor in another example. Input 240a is coupled to the gate of transistor M33. The drain of transistor M33 is coupled to the inductor L31 and the anode of diode D32. The source of transistor M33 and capacitor C34 are coupled together and to the input 240b. Current sense circuit 312 is a sense resistor (e.g., 100 milli-ohms) in one example. The sense resistor may be coupled in series with inductor L31, between inductor L31 and the anode of diode D32. The voltage across the sense resistor is proportional to the current lin. An amplifier may be included to amplify the voltage across the sense resistor to produce the signal I_IND at the inductor current sense output 240d.

FIG. 4 is a block diagram of clock generator 286, in an example. Clock generator 286 includes a clock tree circuit 402 and a multiplexer 404. Clock tree circuit 402 has a selection input 402a (which is coupled to input 286a) and clock outputs 402b and 404c. Clock tree circuit 402 generates multiple clock signals at various frequencies, one of which is selected as the output CLOCK1 at clock output 402b based on CLOCK1_SEL. Clock tree circuit 402 produces its highest frequency output clock, CLOCK_MAX, at its output 402c regardless of the value of CLOCK1_SEL. Multiplexer 404 has inputs 404a and 404b, selection input 404d (which is coupled to input 286b), and output 404c (coupled to output 286c). HP_EN from high power detection circuit 284 is provided to the multiplexer's selection input 404d. When HP_EN is logic low, multiplexer 404 selects CLOCK1 from clock tree circuit 402 as the output clock CLOCK2. When HP_EN is logic high, multiplexer 404 selects CLOCK_MAX from clock tree circuit 402 as the output clock CLOCK2. In one example, the frequency of CLOCK_MAX is double that of the highest frequency of CLOCK1 that clock tree circuit 402 would output based on CLOCK1_SEL.

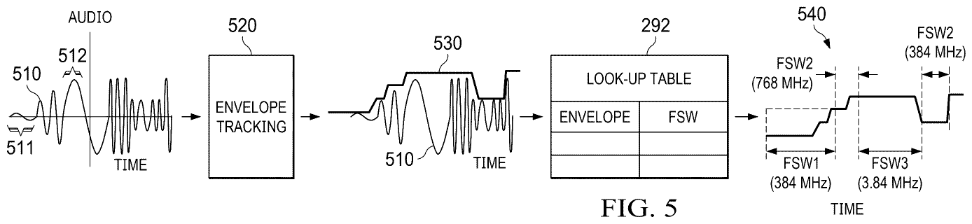

FIG. 5 is a diagram illustrating the operation of envelope tracker 290. FIG. 5 includes an example input audio signal AUDIO IN 510. In general, audio can be characterized as having a fairly high crest factor. The crest factor is the ratio of the peak magnitude of the audio to its average. A high crest factor audio signal means that the audio signal has extended periods of relatively low amplitude audio 511 as well as short duration, high amplitude peaks 512. At the lower amplitude audio levels 511, amplifier 120 provides relatively low power (e.g., 1 watt) to speaker 140. However, at the higher amplitude peaks 512, amplifier 120 provides higher power levels (e.g., 7 watts) to speaker 140. Accordingly, boost converter 110 responds to the changing power demands of amplifier 120 by supplying to amplifier 120 the varying power levels corresponding to the audio signal being played through speaker 140. Envelope tracker 290 implements envelope tracking 520 to generate an envelope 530 of the audio signal 510. Envelope 530 is provided to LUT 292 as an index. LUT 292 maps the envelope value to a switching frequency, Fsw. In one example, LUT 292 includes multiple ranges of envelope values and a different switching frequency mapped to each envelope value range. In one example, boost converter 110 is a synchronous boost converter in which the switching frequencies in LUT 292 are multiple integers of a base switching frequency.

In the example of FIG. 5, the base switching frequency is 384 KHz, and the other switching frequencies are integer multiples of 384 KHz. Waveform 540 in FIG. 5 illustrates an example mapping between audio envelope 530 and switching frequencies. Envelope tracker 290 applies a base switching frequency, Fsw1, of 384 KHz to a first audio envelope range, a second switching frequency, Fsw2, of 768 KHz to the next higher envelope range, and a third switching frequency, Fsw3, of 3.84 KHz for the next higher envelope range. In this example, the envelope of the audio signal 510 is divided into three bins and a different switching frequency is mapped to each of the three bins. Other examples may have fewer or more than three bins and, accordingly, fewer or more than three switching frequencies. The frequency of CLOCK1 from envelope tracker 290 is one of the frequencies from LUT 292 and is based on the bin corresponding to the audio envelope 530. Envelope tracker 290 also may generate signal 293 to a logic state for an audio envelope below a relatively low threshold, responsive to which switch SW1 provides VIN directly to the output 112 of power stage 240, thereby bypassing the power stage of boost converter 110.

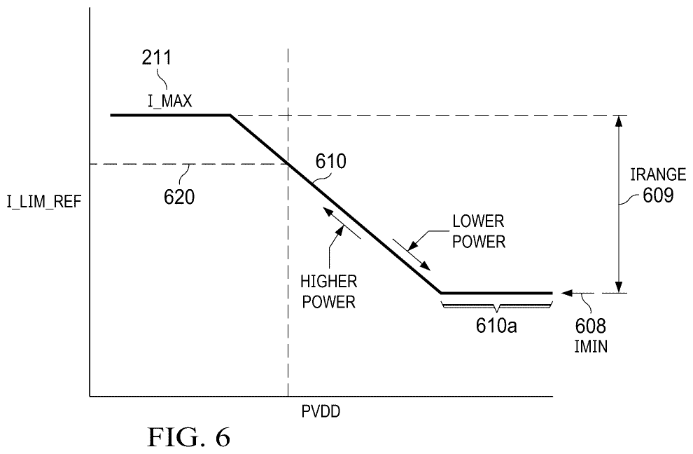

FIG. 6 is a graph 610 of the peak reference current, I_LIM_REF, versus voltage PVDD from boost converter 110. As described above, for a given switching frequency, PVDD varies inversely with output power. FIG. 6 illustrates that as the power draw from boost converter 110 increases, voltage PVDD decreases, and as the power draw decreases, voltage PVDD increases. Further, as described above, boost converter 110 increases the level of the peak reference current I_LIM_REF as PVDD decreases/power draw increases. High power detection circuit 284 determines when the peak reference current I_LIM_REF reaches or exceeds a threshold 620, which is close to the maximum current I_MAX 211. In response to determining that the peak reference current I_LIM_REF reaches or exceeds threshold 620 (is within the threshold noted above of I_MAX 211), high power detection circuit 284 asserts output signal HP ENABLE 295 to, for example, a logic high state. Clock generator 286 responds to a logic high assertion of output signal HP ENABLE 295 by increasing, e.g., doubling, the switching frequency of CLOCK2 to PWM generator 230 from the highest switching frequency that otherwise would have been provided based on CLOCK1_SEL. High power detection circuit 284 asserts output signal HP ENABLE 295 to the logic high state commensurate with audio signal 510 (FIG. 5) being at or near a high amplitude peak 512. Clock generator 286 responds by changing the state of multiplexer 404 to select CLOCK_MAX at input 404b as its CLOCK2 for the high amplitude audio peaks to provide increased power to amplifier 120.

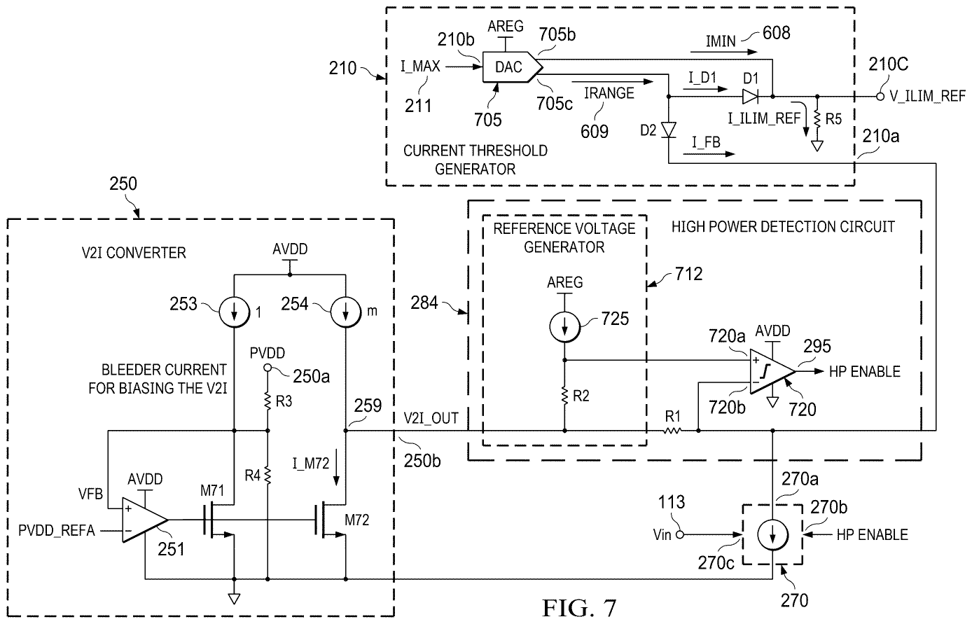

As the power draw on boost converter 110 decreases, peak reference current I_LIM_REF also decreases below threshold 620, and high power detection circuit 284 forces its output signal HP ENABLE 295 to, for example, a logic low state. Responsive to the output signal HP ENABLE 295 being at a logic low state, clock generator 286 changes the state of multiplexer 404 to select CLOCK1 from clock tree circuit 402 as its output clock CLOCK2, thereby providing CLOCK2 to PWM generator 230 at a frequency based on LUT 292. Graph 610 includes a flat region 610a at an I_LIM_REF current level equal to IMIN 608. FIG. 6 also illustrates that the difference between I_MAX 211 and IMIN is a current IRANGE 609. Currents IMIN and IRANGE are further explained below with reference to FIG. 7.

FIG. 7 is a circuit schematic illustrating examples of V2I converter 250, high power detection circuit 284, and current threshold generator 210. The V2I converter 250 includes an amplifier 251, transistors M71 and M72, resistors R3 and R4, and current sources 253 and 254. Resistors R3 and R4 are coupled in series between input 250a and ground thereby forming a voltage divider for voltage PVDD. The connection between resistors R3 and R4 is coupled to the positive input of amplifier 251. The negative input of amplifier 251 receives voltage PVDD_REFA from DAC 296. As described above, voltage estimator 160 determines the value PVDD_REFD, which is converted to an analog signal equivalent PVDD_REFA, based on various factors such as those in Eq. (1). The output of amplifier M71 is coupled to the gates of transistors M71 and M72. The sources of transistors M71 and M72 are coupled to ground. Current source 253 is coupled to the drain of transistor M71 and to the positive input of amplifier 251. Current source 254 is coupled to the drain of transistor M72 and to the output 250b at node 259. Current sources 253 and 254 provide current for biasing V2I converter 250.

High power detection circuit 284 includes a reference voltage generator 712, a resistor R1, and a comparator 720. Reference voltage generator 712 includes a current source 725 coupled to a resistor R2 and to the positive input of comparator 720. Resistor R1 has one terminal coupled to output 250b and another terminal coupled to the negative input of comparator 720. Comparator 720 generates the output signal HP ENABLE 295 at its output.

Current threshold generator 210 includes a digital-to-analog converter (DAC) 705, diodes D1 and D2, and a resistor R5. The input of DAC 705 is the input 210b noted above and receives a digital value representing the maximum current I_MAX 211. DAC 705 has outputs 705b and 705c, each providing a current. Output 705b provides current IMIN 608, and output 705c provides current IRANGE 609. The anodes of diodes D1 and D2 are coupled to output 705c of DAC 705. The cathode of diode D1 is coupled to output 705b and to output 210c.

Resistor R5 has a terminal coupled to output 210c and another terminal coupled to ground. The block diagram of FIG. 2 shows the peak reference current I_LIM_REF provided to the negative input of comparator 220. In the example of FIG. 7, the peak reference current I_LIM_REF flows through resistor R5, thereby generating a voltage V_ILIM_REF which is proportional to peak reference current I_LIM_REF. In one example, comparator 220 is a voltage comparator and its input signals are voltages. Accordingly, peak reference current I_LIM_REF is converted to a voltage by resistor R5. Similarly, the signal I_IND indicative of the current through inductor L31 of power stage 240 also is a voltage indicative of the current through inductor L31.

The current through resistor R5 is equal to or greater than current IMIN 608, thereby setting the minimum current level IMIN for the peak reference current I_LIM_REF. Current IRANGE 609 can flow through diode D1, through diode D2, or divide between diodes D1 and D2. The current through diode D1 is current I_D1, and the current through diode D2 is current I_FB. Accordingly, the sum of currents I_FB and I_D1 is current IRANGE 609. The larger is current I_FB, the smaller is current I_D1, and the smaller is current I_FB, the larger is current I_D1. The sum of currents I_D1 and IMIN 609 is peak reference current I_LIM_REF. Accordingly, an increase in current I_FB causes a decrease in peak reference current I_LIM_REF, and a decrease in current I_FB causes a decrease in in peak reference current I_LIM_REF.

The V2I converter 250 sets the magnitude of current I_FB. The current from current source 254 and current I_FB flow into node 259. Current I_M72 flows from node 259 and through transistor M72. Accordingly, the sum of the current from current source 254 and current I_FB equals current I_M72. The current from current source 254 is a fixed current. The current I_M72 is set by the gate-to-source voltage (Vgs) of transistor M72. The Vgs of transistor M72 is the voltage at the output of amplifier 251. Amplifier 251 amplifies the difference between voltages VFB and PVDD_REFA. Because voltage VFB is proportional to voltage PVDD, the Vgs of transistor M72 is proportional to voltage PVDD. Accordingly, current I_M72 is proportional to voltage PVDD. Because the currents at node 259 must balance, as voltage PVDD decreases, current I_M72 also decreases and current I_FB decreases. Similarly, as voltage PVDD increases, current I_M72 increases and current I_FB increases. Accordingly, current I_FB is proportional to voltage PVDD. As voltage PVDD decreases, current I_FB decreases and current I_D1 increases and, as a result, peak reference current I_LIM_REF increase. When voltage PVDD decreases to the point that it is equal to or less than voltage PVDD_REFA, transistor M72 turns off, current I_FB is 0 amperes, and peak reference current I_LIM_REF equals the sum of currents IRANGE 608 and IMIN 608, which is the maximum current I_MAX. As voltage PVDD increases, current I_FB increases and current I_D1 decreases and, as a result, peak reference current I_LIM_REF decreases.

Relative to the voltage at output 250b, comparator 720 compares the voltage across resistor R2 to the voltage across resistor R1. The voltage across resistor R2 is a fixed reference voltage set by the current from current source 725. The voltage across resistor R1 is set by the current I_FB flowing through resistor R1. As described above, current I_FB is inversely related to the peak reference current I_LIM_REF. When the peak reference current I_LIM_REF is less than threshold 620 (FIG. 6), current I_FB is large enough that the voltage on the negative input of comparator 720 is larger than the fixed reference voltage across resistor R2, and output signal HP ENABLE 295 is logic low. However, when the peak reference current I_LIM_REF reaches the threshold 620, current I_FB is smaller enough that the voltage on the negative input of comparator 720 is smaller than the fixed reference voltage across resistor R2, responsive to which comparator 720 forces output signal HP ENABLE 295 to a logic high state.

When high power detection circuit 284 determines that peak reference current I_LIM_REF is at or above threshold 620 (FIG. 6), high power detection circuit 284 asserts its output signal HP ENABLE 295 to a logic high state. Responsive to this logic high state, clock generator 286 increases the switching frequency of boost converter 110. When that happens, the magnitude of the ripple current decreases and, for the same level of peak reference current I_LIM_REF, the average inductor current increases. A sudden increase in average inductor current leads to a sudden jump in voltage PVDD, which may result in audio artefacts in the audio produced by speaker 140. Ripple compensation circuit 270 addresses this problem.

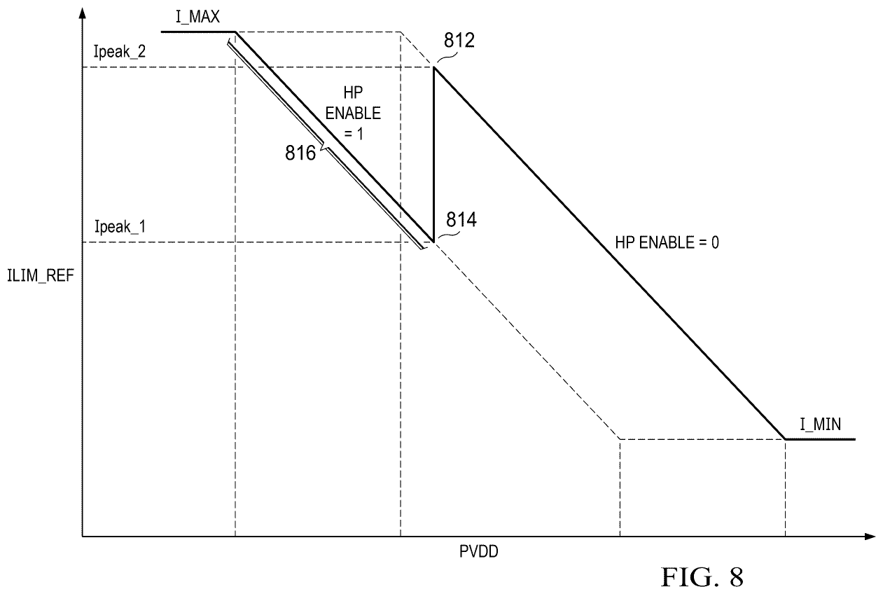

FIG. 8 is a graph 810 of peak reference current I_LIM_REF versus voltage PVDD with the use of ripple compensation circuit 270. As the level of the peak reference current I_LIM_REF reaches an upper threshold Ipeak_2 at point 812, ripple compensation circuit 270, which also receives the signal HP ENABLE 295, responds to the positive assertion of signal HP ENABLE 295. Such response includes a sudden decrease in peak reference current I_LIM_REF from Ipeak_2 down to Ipeak_1. Although the switching frequency of boost converter 110 suddenly increases, because its peak reference current I_LIM_REF suddenly decreases down to threshold Ipeak_1, the average inductor current before and after the sudden change in switching frequency remains approximately the same. The peak reference current I_LIM_REF may continue increasing along segment 816 if the load on boost converter 110 continues to increase. As the load on boost converter 110 decreases, peak reference current I_LIM_REF eventually drops to point 814. At that point, high power detection circuit 284 forces signal HP ENABLE 195 back to a logic 0 state. As a result, clock generator 286 reduces the switching frequency of CLOCK2, e.g., by a factor of 2, and, as a result, ripple compensation circuit 270 increases peak reference current I_LIM_REF back to threshold Ipeak_2 thereby resulting in a negligible sudden step in the average inductor current.

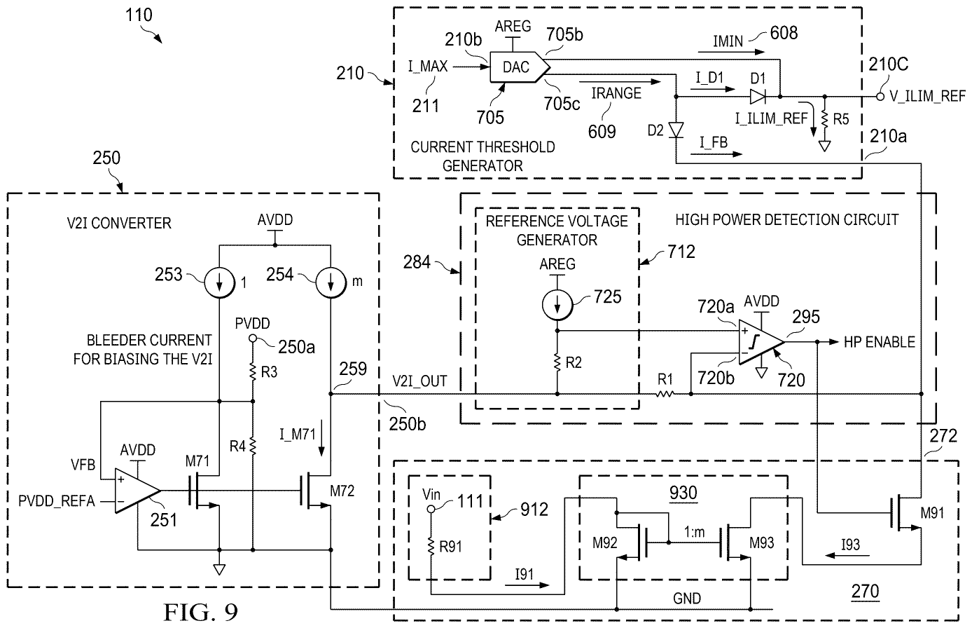

FIG. 9 is a similar circuit schematic as in FIG. 7 but further includes an example circuit implementation of ripple compensation circuit 270. Ripple compensation circuit 270 includes a current source circuit 912, a current mirror 930, and a transistor M91. Current source circuit 912 includes resistor R91. Current mirror 930 includes transistors M92 and M93. The current mirror ratio of current mirror 930 is 1:m where m is an integer equal to or greater than 1. Transistors M91-N93 are NFETs in this example. The gates of transistors M92 and M93 are coupled together and to the drain of transistor M92. The sources of transistors M92 and M93 are coupled together at ground. Current source circuit 912 has a terminal coupled to input voltage terminal 111 and another terminal coupled to the drain of transistor M92. The source of transistor M91 is coupled to the drain of transistor M93, and the drain of transistor M91 is coupled to output 272. The gate of transistor M91 is coupled to the output of comparator 720 and, accordingly, receives signal HP ENABLE 295. Signal HP ENABLE 295 turns on transistor M91 when it is logic high and turns off transistor M91 when it is logic low.

The current I91 through resistor R91, which also flows through transistor M92, is based on the magnitude of input voltage Vin and the resistance of resistor R91. When signal HP ENABLE 295 is logic high, current I91 is mirrored through transistor M93 as current I93, which also causes an increase in current I_FB. An increase in current I_FB due to transistor M91 turning on causes a commensurate decrease in peak reference current I_LIM_REF corresponding to the drop in the peak reference current I_LIM_REF from threshold Ipeak_2 to I_peak1 (FIG. 8). If the load on boost converter 110 decreases and high-power detection circuit 284 de-asserts signal HP ENABLE 295 from logic 1 to logic 0, transistor M91 turns off. Transistor M91 being off causes a decrease in current I_FB and a commensurate increase in peak reference current I_LIM_REF. The increase in current I_LIM_REF corresponds to the increase in the peak reference current I_LIM_REF from threshold I_peak1 to I_peak2.

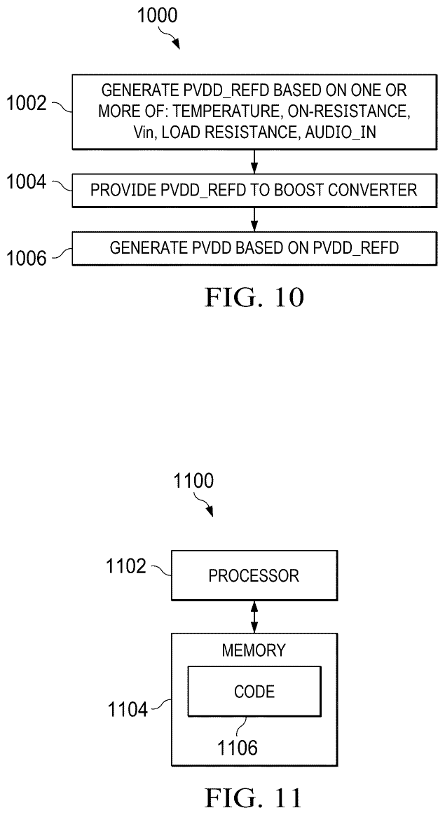

FIG. 10 is a flow diagram 1000 in an example. At operation 1002, the value PVDD_REFD is generated based on one or more of the following parameters: temperature, the on-resistance of transistors M1-M4, the input voltage Vin, the load resistance RLOAD (e.g., resistance of speaker 140, and AUDIO_IN. In one example, PVDD_REFD is determined in accordance with equation Eq. (1). At operation 1004, the value PVDD_REFD is provided to boost converter 110, for example, to DAC 296 to be converted to an analog signal which is then provided to V2I converter 250. At operation 1006, boost converter 110 generates output voltage PVDD based on the value PVDD_REFD.

FIG. 11 is a diagram of a system 1100 including a processor 1102 coupled to memory 1104. Memory 1104 stores machine-executable code 1106 that can be retrieved and executed by processor 1102. Upon executing machine-executable code 1106, processor 1102 can perform any or all of the functionality described herein attributed to voltage estimator 160. In other examples, as described above the voltage estimator 160 can be implemented by a digital circuit or an analog circuit. When executed, machine-executable code 1106 can also implement the functionality of some or all of the clock selector 150.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection (for example by way of a ground terminal) applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An apparatus, comprising:
an audio amplifier having a terminal;
voltage estimator circuitry having a temperature input and an output, the voltage estimator circuitry configured to generate a value at the output of the voltage estimator circuitry based on a temperature value at the temperature input of the voltage estimator circuitry; and
a boost converter having a first terminal, a second terminal, and a third terminal, the first terminal coupled to an input voltage terminal, the second terminal of the boost converter coupled to the terminal of the audio amplifier, and the third terminal of the boost converter coupled to the output of the voltage estimator circuitry, the boost converter configured to generate a voltage at the second terminal of the boost converter based on the value at the output of the voltage estimator circuitry.

2. The apparatus of claim 1, further comprising a non-volatile memory configurable to store a resistance value indicative of a resistance of the audio amplifier, and wherein the voltage estimator circuitry is configured to generate the value based on the temperature value and the resistance value.

3. The apparatus of claim 2, wherein the voltage estimator circuitry is configured to determine a second-order polynomial based on the temperature value, multiply the second-order polynomial by the resistance value to generate a product, and use the product to determine the value.

4. The apparatus of claim 2, wherein the non-volatile memory is configurable to store a load resistance value, and wherein the voltage estimator circuitry is configured to generate the value also based on the load resistance value.

5. The apparatus of claim 1, further comprising a non-volatile memory configurable to store a load resistance value, and wherein the voltage estimator circuitry is configured to generate the value also based on the load resistance value.

6. The apparatus of claim 1, wherein the temperature input is a first input of the voltage estimator circuitry, the voltage estimator circuitry has a second input coupled to the input voltage terminal, and the voltage estimator circuitry configured to generate the value based on both the temperature value and a voltage at the input voltage terminal.

7. The apparatus of claim 1, wherein the voltage estimator circuitry is configured to generate the value based on a second-order polynomial, and the second-order polynomial is based on the temperature value.

8. The apparatus of claim 1, wherein the boost converter includes a voltage-to-current (V2I) converter having a first input and a second input, the first input of the V2I converter coupled to the second terminal of the boost converter, and the second input of the V2I converter coupled to the output of the voltage estimator circuitry.

9. The apparatus of claim 1, further comprising a temperature sensor coupled to the temperature input and a speaker coupled to the amplifier.

10. An apparatus, comprising:
an audio amplifier having a terminal;
voltage estimator circuitry having an output, the voltage estimator circuitry configured to generate a value at the output based on an audio signal and based on a load resistance; and
a boost converter having a first terminal, a second terminal, and a third terminal, the first terminal coupled to an input voltage terminal, the second terminal coupled to the terminal of the audio amplifier, and the third terminal coupled to the output of the voltage estimator circuitry, the boost converter configured to generate a voltage at the second terminal based on the value at the output of the voltage estimator circuitry.

11. The apparatus of claim 10, wherein the voltage estimator circuitry is configured to generate the value at the output of the voltage estimator circuitry based on a square of the audio signal.

12. The apparatus of claim 10, wherein the voltage estimator circuitry is configured to generate the value at the output of the voltage estimator circuitry based on a ratio of a square of the audio signal to the load resistance.

13. The apparatus of claim 10, wherein the voltage estimator circuitry is configured to generate the value at the output of the voltage estimator circuitry based on a ratio of a square of the audio signal to the load resistance and also based on an input voltage provided to the first terminal.

14. The apparatus of claim 10, further comprising a temperature sensor coupled to the voltage estimator circuitry, and the voltage estimator circuitry configured to generate the value also based on a temperature value from the temperature sensor.

15. The apparatus of claim 14, further comprising a non-volatile memory configurable to store a resistance value indicative of a resistance of the audio amplifier, and wherein the voltage estimator circuitry is configured to generate the value at the output of the voltage estimator circuitry also based on the temperature value and the resistance value.

16. The apparatus of claim 15, wherein the voltage estimator circuitry is configured to generate the value at the output of the voltage estimator circuitry based on the resistance value and a second-order polynomial of the temperature value.

17. An apparatus, comprising:
an audio amplifier having a terminal;
voltage estimator circuitry having a temperature input, a second input, and an output, the voltage estimator circuitry configured to generate a value at the output of the voltage estimator circuitry based on a temperature value at the temperature input and based on an audio signal; and
a boost converter having a first terminal, a second terminal, and a third terminal, the first terminal coupled to an input voltage terminal, the second terminal coupled to the terminal of the audio amplifier, and the third terminal coupled to the output of the voltage estimator circuitry, the boost converter configured to generate a voltage at the second terminal based on the value.

18. The apparatus of claim 17, wherein the voltage estimator circuitry is configured to determine a square of the audio signal and generate the value at the output of the voltage estimator circuitry based on the square.

19. The apparatus of claim 18, wherein the voltage estimator circuitry is configured to generate the value at the output of the voltage estimator circuitry based on a ratio of the square to a voltage at the input voltage terminal.

20. The apparatus of claim 17, further comprising a non-volatile memory coupled to the voltage estimator circuitry and configurable to a resistance value indicative of a resistance of the audio amplifier, and wherein the voltage estimator circuitry is configured to generate the value at the output of the voltage estimator circuitry based on the resistance value.
